(19) United States
(12) Patent Application Publication
(10) Pub. No.: US 2023/0152697 A1
(43) Pub. Date: May 18, 2023

(54) PHOTORESIST COMPOSITIONS AND PATTERN FORMATION METHODS

(71) Applicant: Rohm and Haas Electronic Materials LLC, Marlborough, MA (US)

(72) Inventors: KE YANG, CUPERTINO, CA (US); MINGQI LI, SHREWSBURY, MA (US); CHOONG-BONG LEE, WESTBOROUGH, MA (US); CHENG-BAI XU, SOUTHBOROUGH, MA (US); IRVINDER KAUR, NORTHBOROUGH, MA (US); TOMAS MARANGONI, Orono, ME (US); JOSHUA KAITZ, SHREWSBURY, MA (US)

(21) Appl. No.: 17/940,682

(22) Filed: Sep. 8, 2022

Related U.S. Application Data
(60) Provisional application No. 63/251,029, filed on Sep. 30, 2021.

(51) Int. Cl. G03F 7/039; C08F 220/28; C08F 220/18; G03F 7/004

(52) U.S. Cl. CPC G03F 7/0392; C08F 220/281; C08F 220/283; C08F 220/1808; G03F 7/0045

(57) ABSTRACT

Photoresist compositions comprise: an acid-sensitive polymer comprising a repeating unit comprising an ester acetal group, wherein the acid-sensitive polymer is free of tertiary alkyl ester groups and is substantially free of aromatic groups; a material comprising a base-labile group; a photoacid generator compound that is free of fluorine which generates an acid having a pKa of -2 or greater, and wherein the photoresist composition is free of photoacid generators that generate an acid having a pKa of less than -2; and a solvent.. The photoresist compositions and pattern formation methods using the photoresist compositions find particular use in the formation of fine lithographic patterns in the semiconductor manufacturing industry.

### BACKGROUND OF THE INVENTION

### 1. Field of the Invention

The invention relates generally to the manufacture of electronic devices. More specifically, this invention relates to photoresist compositions and to pattern formation methods using such compositions. The compositions and methods find particular use in the formation of lithographic patterns useful in the manufacture of semiconductor devices.

### 2. Description of the Related Art

In the semiconductor manufacturing industry, photoresist layers are used for transferring an image to one or more underlying layers, such as metal, semiconductor or dielectric layers, disposed on a semiconductor substrate, as well as to the substrate itself. To increase the integration density of semiconductor devices and allow for the formation of structures having dimensions in the nanometer range, photoresist compositions and photolithography processing tools having high-resolution capabilities have been and continue to be developed.

Chemically amplified photoresist compositions are conventionally used for high-resolution processing. Such compositions typically employ a polymer having acid-labile groups, a photoacid generator (PAG) and a solvent. Pattern-wise exposure of a layer formed from such photoresist composition to activating radiation causes the acid generator to form an acid which, during post-exposure baking, causes cleavage of the acid-labile groups in exposed regions of the photoresist layer. This creates a difference in solubility characteristics between exposed and unexposed regions of the layer in a developer solution. In a positive tone development (PTD) process, exposed regions of the photoresist layer become soluble in aqueous base developer and are removed from the substrate surface, and unexposed regions, which are insoluble in the developer, remain after development to form a positive image. The resulting relief image permits selective processing of the substrate.

One approach to achieving nm-scale feature sizes in semiconductor devices is the use of short wavelengths of light, for example, 193 nm or less, during exposure of chemically amplified photoresists. To further improve lithographic performance, immersion lithography tools have been developed to effectively increase the numerical aperture (NA) of the lens of the imaging device, for example, an immersion scanner having an ArF (193 nm) light source. This is accomplished by use of a relatively high refractive index fluid, typically water, between the last surface of the imaging device and the upper surface of the photoresist-coated semiconductor wafer. ArF immersion tools are currently pushing the boundaries of lithography to the 16 nm and 14 nm nodes with the use of multiple (double or higher order) patterning. However, with increases in lithographic resolution, linewidth roughness (LWR) of the photoresist patterns has become of greater importance in creating high-resolution patterns. Excessive linewidth variation along the length of a gate, for example, can have adverse consequences on threshold voltage and may increase leakage current, both of which can adversely impact device performance and yield. Photoresist compositions allowing for desired LWR characteristics would therefore be desired.

Advanced ArF photoresist compositions typically include a polymer having tertiary alkyl ester groups and an ionic PAG compound that generates a superacid during post-exposure bake. A superacid is generally required to efficiently cleave the tertiary alkyl ester groups in exposed regions of the photoresist layer under normal processing conditions due to their relatively high activation energy. Such PAGs are typically onium salts that include fluorinated alkylsulfonate anions in order to achieve superacidity of the conjugate acid. There is, however, a desire in the semiconductor industry to replace certain fluorinated PAGs with greener alternatives. Also, from a technical standpoint, fluorinated chains on PAGs typically impart hydrophobicity (low surface energy) to the PAGs, which can result in non-homogeneous distribution of the PAG in a photoresist layer through the layer depth. This can severely impact pattern fidelity of the resulting photoresist patterns.

There is thus a need in the art for improved photoresist compositions and pattern formation methods which address one or more problems associated with the state of the art.

### SUMMARY OF THE INVENTION

In accordance with a first aspect of the invention, photoresist compositions are provided. The photoresist compositions comprise: an acid-sensitive polymer comprising a repeating unit comprising an ester acetal group, wherein the acid-sensitive polymer is free of tertiary alkyl ester groups and is substantially free of aromatic groups; a material comprising a base-labile group; a photoacid generator compound that is free of fluorine which generates an acid having a pKa of -2 or greater, and wherein the photoresist composition is free of photoacid generators that generate an acid having a pKa of less than -2; and a solvent.

Also provided are pattern formation methods. The pattern formations methods comprise: (a) applying a layer of a photoresist composition as described herein on a substrate; (b) pattern-wise exposing the photoresist composition layer to activating radiation; and (c) developing the exposed photoresist composition layer to provide a resist relief image.

The terminology used herein is for the purpose of describing particular embodiments only and is not intended to be limiting of the invention. The singular forms “a”, “an” and “the” are intended to include singular and plural forms, unless the context indicates otherwise. All ranges disclosed herein are inclusive of the endpoints, and the endpoints are independently combinable with each other. When an element is referred to as being “on” or “over” another element, it may be directly in contact with the other element or intervening elements may be present therebetween. In contrast, when an element is referred to as being “directly on” another element, there are no intervening elements present.

As used herein, an “acid-labile group” refers to a group in which a bond is cleaved by action of an acid, optionally and typically with thermal treatment, resulting in a polar group, for example, a carboxylic acid or an alcohol group, being formed on the polymer, and optionally and typically with a moiety that becomes disconnected from the polymer when such bond is cleaved. Acid-labile groups include, for example, tertiary alkyl ester groups and acetal groups. Acid-labile groups are also commonly referred to in the art as “acid-cleavable groups,” “acid-cleavable protecting groups,” “acid-decomposable groups,” “acid-labile protecting groups,” “acid-leaving groups,” and “acid-sensitive groups.”

Unless otherwise indicated, a group that is “substituted” refers to a group having one or more of its hydrogen atoms replaced with one or more substituents. Exemplary substituent groups include, but are not limited to, hydroxy (—OH), halogen (e.g., —F, —Cl, —I, —Br), C₁₋₁₈ alkyl, C₁₋₈ haloalkyl, C₃₋₁₂ cycloalkyl, C₆₋₁₂ aryl having at least one aromatic ring (e.g., phenyl, biphenyl, naphthyl, or the like, each ring either substituted or unsubstituted aromatic), C₇₋₁₉ arylalkyl having at least one aromatic ring, C₇₋₁₂ alkylaryl, and combinations thereof. For purposes of carbon number determination, when a group is substituted, the number of carbon atoms of the group is the total number of carbon atoms in such group excluding those of any substituents.

### DETAILED DESCRIPTION OF THE INVENTION

The photoresist compositions of the invention comprise: an acid-sensitive polymer comprising a repeating unit comprising an ester acetal group, wherein the acid-sensitive polymer is free of tertiary alkyl ester groups and is substantially free of aromatic groups; a material comprising a base-labile group; a photoacid generator compound that is free of fluorine which generates an acid having a pKa of -2 or greater, and wherein the photoresist composition is free of photoacid generators that generate an acid having a pKa of less than -2; and a solvent. The inventors have surprisingly discovered that particular photoresist compositions of the invention can achieve notably improved lithographic performance, such as reduced linewidth roughness (LWR) and improved photosensitivity. As used herein, “substantially free of aromatic groups” means less than 15 mol%, and preferably less than 10 mole%, less than 5 mol%, less than 2 mol%, or completely free of aromatic groups.

The acid-sensitive polymer comprises a repeating unit comprising an ester acetal group. This group, upon photoacid-catalyzed decomposition, forms a carboxylic acid group on the polymer. The ester acetal group is preferably of the formula (1)

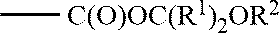

wherein: R¹ is independently hydrogen, fluorine, C₁₋₂₀ alkyl, monocyclic or polycyclic C₃₋₂₀ cycloalkyl, C₂₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably hydrogen, C₁₋₆ alkyl or monocyclic or polycyclic C₃₋₁₀ cycloalkyl, each of which except hydrogen and fluorine is substituted or unsubstituted, each R¹ optionally including as part of its structure one or more groups chosen from —O—, —C(O)—, —C(O)—O—, or —S—, and the R¹ groups together optionally forming a ring; and R² is C₁₋₂₀ alkyl, monocyclic or polycyclic C₃₋₂₀ cycloalkyl, C₂₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably C₁₋₆ alkyl or monocyclic or polycyclic C₃₋₁₀ cycloalkyl, each of which is substituted or unsubstituted, R² optionally including as part of its structure one or more groups chosen from —O—, —C(O)—, —C(O)—O—, or —S—, and one R¹ together with R² optionally forming a ring.

In some embodiments, the repeating unit comprising an ester acetal group is formed from a monomer comprising a carbon-carbon unsaturated vinylic group. As used herein, a “carbon-carbon unsaturated vinyl group” refers to a vinyl-containing polymerizable group, and typically may be selected from substituted or unsubstituted C₂-₂₀ alkenyl, substituted or unsubstituted norbonyl, substituted or unsubstituted (meth)acrylic, substituted or unsubstituted vinyl ether, substituted or unsubstituted vinyl ketone, substituted or unsubstituted vinyl ester, or substituted or unsubstituted vinyl aromatic, and preferably selected from a substituted or unsubstituted norbornyl group or a substituted or unsubstituted (meth)acrylic group.

The repeating unit comprising an ester acetal group may, for example, be derived from a monomer of formula (2):

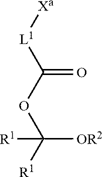

In formula (2), R¹ and R² are as defined above in formula (1). X^{a} is a polymerizable group that may include a carbon-carbon unsaturated vinylic group; L¹ is a single bond or a divalent linking group chosen from substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₂ arylene, substituted or unsubstituted C₃₋₁₂ heteroarylene, or a combination thereof.

The repeating unit comprising an ester acetal group is preferably derived from a monomer of formula (2a):

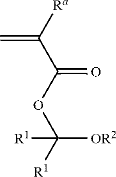

In formula (2a), R¹ and R² are as defined above in formula (1). R^{a} is hydrogen or substituted or unsubstituted C₁₋₁₀ alkyl. Typically, R^{a} is hydrogen or methyl.

Exemplary suitable monomers for forming the repeating unit comprising an ester acetal group include the following:

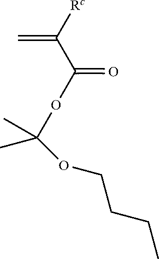

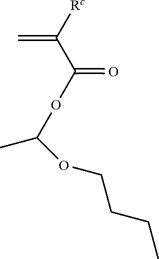

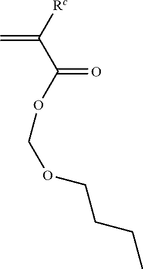

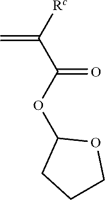

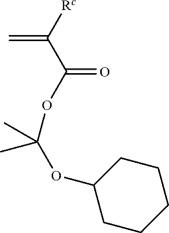

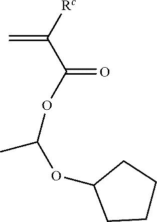

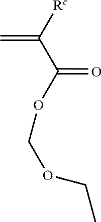

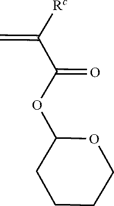

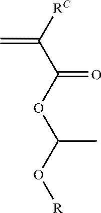

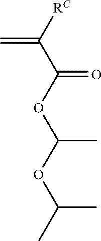

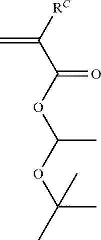

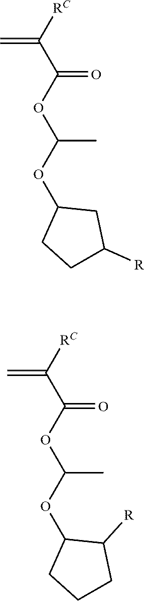

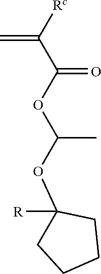

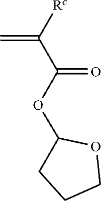

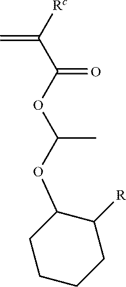

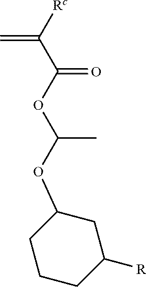

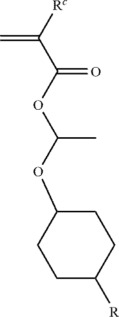

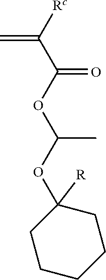

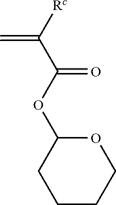

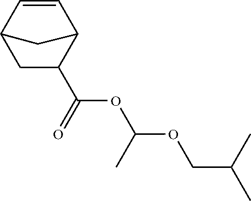

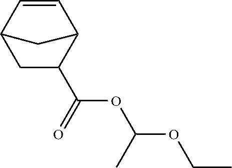

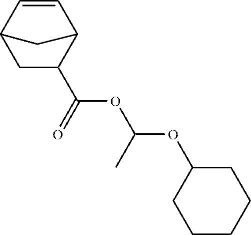

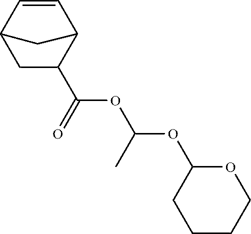

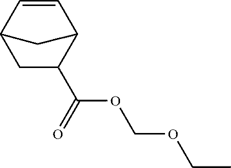

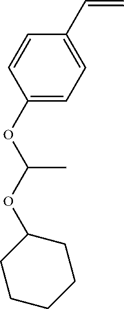

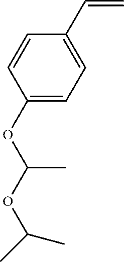

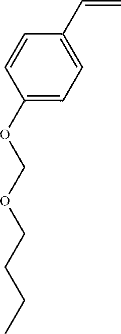

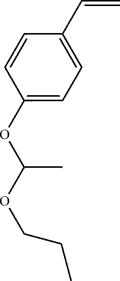

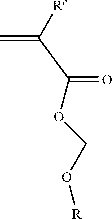

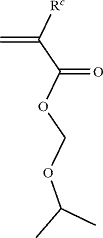

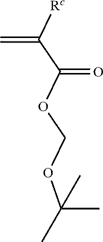

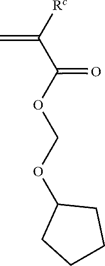

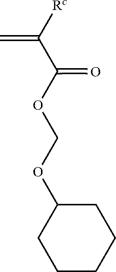

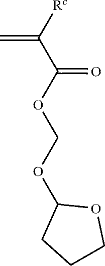

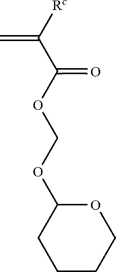

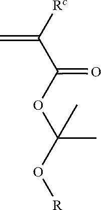

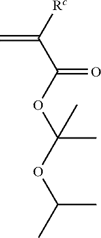

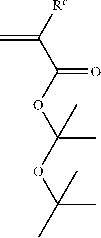

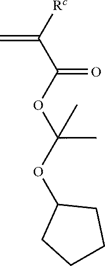

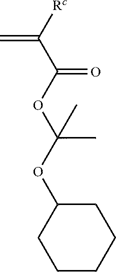

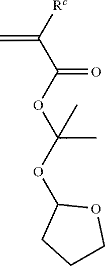

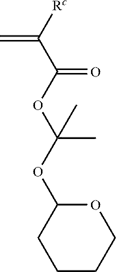

wherein R^{c} is hydrogen or substituted or unsubstituted C₁₋₁₀ alkyl, and R is C₁₋₆ alkyl, typically C₁₋₄ alkyl or C₁₋₂ alkyl.

The photoresist compositions may additionally or alternatively include a repeating unit comprising an ester acetal group derived from a monomer of formula (3):

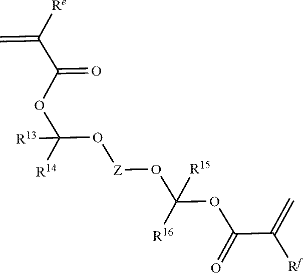

In formula (3), R^{e} and R^{f} are each independently hydrogen or substituted or unsubstituted C₁₋₁₀ alkyl. Preferably, R^{e} and R^{f} are each independently hydrogen or substituted or unsubstituted C₁₋₅ alkyl, typically methyl. R¹³, R¹⁴, R¹⁵, and R¹⁶ are each independently hydrogen, fluorine, C₁₋₂₀ alkyl, monocyclic or polycyclic C₃₋₂₀ cycloalkyl, C₂₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably hydrogen, C₁₋₆ alkyl or monocyclic or polycyclic C₃₋₁₀ cycloalkyl, each of which except hydrogen and fluorine is substituted or unsubstituted, each optionally including as part of its structure one or more groups chosen from —O—, —C(O)—, —C(O)—O—, or —S—. R¹³ and R¹⁴ optionally together may form a ring via a single bond or a divalent linking group. The ring may be monocyclic, non-fused polycyclic, or fused polycyclic, and is typically monocyclic when formed. R¹⁵ and R¹⁶ optionally together may form a ring via a single bond or a divalent linking group. The ring may be monocyclic, non-fused polycyclic, or fused polycyclic, and is typically monocyclic when formed. Z is a divalent linking group. Preferably, Z is substituted or unsubstituted C₁₋₈ alkylene, substituted or unsubstituted C₃₋₈ cycloalkylene, or substituted or unsubstituted C₃₋₈ heterocycloalkylene, substituted or unsubstituted C₆₋₁₂ arylene, or substituted or unsubstituted C₃₋₁₂ heteroarylene, optionally including as part of its structure one or more groups chosen from —O—, —C(O)—, —C(O)—O—, or —S—.

Exemplary suitable monomers of formula (3) include:

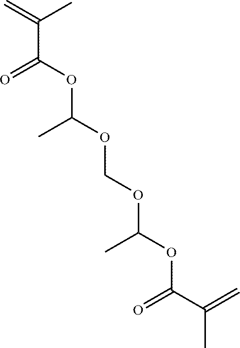 [SMILES: C=C(C)C(=O)OC(C)OCOC(C)OC(=O)C(=C)C]

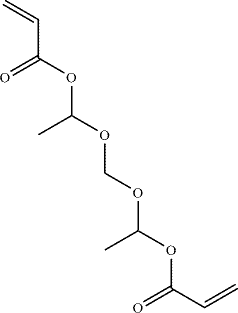 [SMILES: C=CC(=O)OC(C)OCOC(C)OC(=O)C=C]

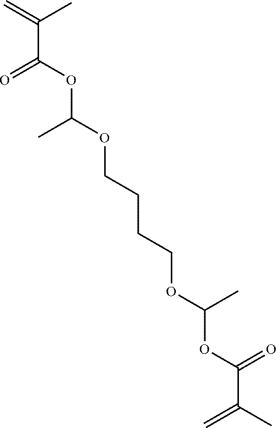 [SMILES: C=C(C)C(=O)OC(C)OCCCCOC(C)OC(=O)C(=C)C]

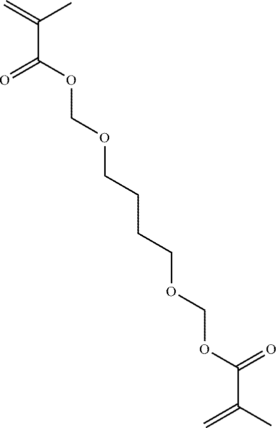 [SMILES: C=C(C)C(=O)OCOCCCCOCOC(=O)C(=C)C]

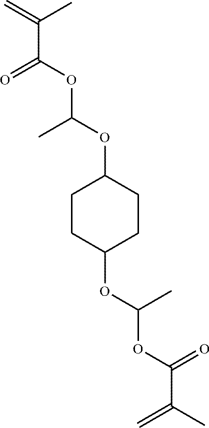 [SMILES: C=C(C)C(=O)OC(C)OC1CCC(OC(C)OC(=O)C(=C)C)CC1]

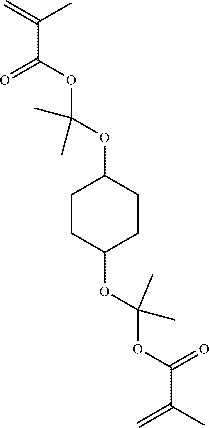 [SMILES: C=C(C)C(=O)OC(C)(C)OC1CCC(OC(C)(C)OC(=O)C(=C)C)CC1]

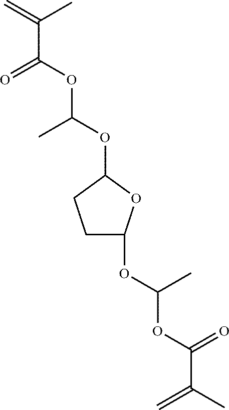 [SMILES: C=C(C)C(=O)OC(C)OC1CCC(OC(C)OC(=O)C(=C)C)O1]

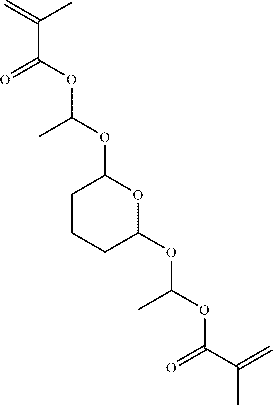 [SMILES: C=C(C)C(=O)OC(C)OC1CCCC(OC(C)OC(=O)C(=C)C)O1]

The acid-sensitive polymer typically comprises repeating units comprising an ester acetal group in a combined amount from 1 to 50 mol%, typically from 1 to 40 mol%, and more typically from 5 to 30 mol%, based on total moles of repeating units in the polymer.

The acid-sensitive polymer typically includes one or more additional repeating units. The additional units may be selected for purposes of adjusting properties of the photoresist composition or layers formed therefrom, for example, solubility in the formulation solvent or developer, or for increased etch resistance. Exemplary additional units may be formed from monomer-types including, for example, one or more of (meth)acrylate, vinyl ether, vinyl ketone, or vinyl ester, with (meth)acrylate being typical. Such additional units may contain functional groups chosen, for example, from lactone groups and base-soluble groups. The one or more additional repeating units if present in the acid-sensitive polymer, may be used in an amount of up to 90 mol%, typically from 3 to 50 mol%, based on total repeating units of the acid-sensitive polymer.

Suitable repeating units containing a lactone group may, for example, be derived from a monomer of formula (4):

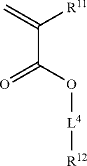

In formula (4), R¹¹ is hydrogen, fluorine, cyano, a substituted or unsubstituted C₁₋₁₀ alkyl, or a substituted or unsubstituted C₁₋₁₀ fluoroalkyl. Preferably, R¹¹ is hydrogen, fluorine, or substituted or unsubstituted C₁₋₅ alkyl, typically methyl. L⁴ may be a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted C₇₋₃₀ arylalkylene, or substituted or unsubstituted C₁₋₃₀ heteroarylene, or substituted or unsubstituted C₃₋₃₀ heteroarylalkylene, wherein L⁴ optionally may further include one or more groups chosen, for example, from —O—, —C(O)—, —C(O)—O—, —S—, —S(O)₂—, and —N(R⁴⁴)—S(O)₂—, wherein R⁴⁴ may be hydrogen, a straight chain or branched C₁₋₂₀ alkyl, monocyclic or polycyclic C₃₋₂₀ cycloalkyl, or monocyclic or polycyclic C₃₋₂₀ heterocycloalkyl. R¹² is a lactone-containing group, for example, a monocyclic, polycyclic, or fused polycyclic C₄₋₂₀ lactone-containing group.

Non-limiting examples of monomers of formula (4) include:

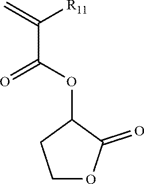

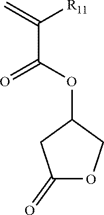

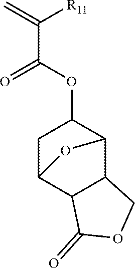

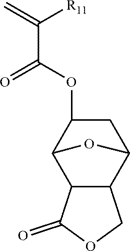

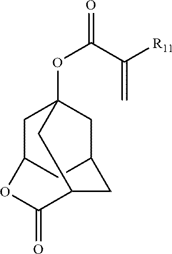

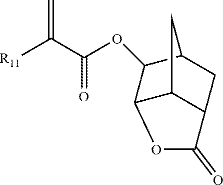

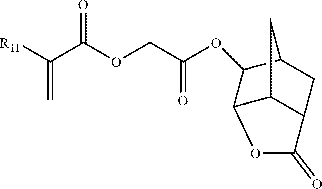

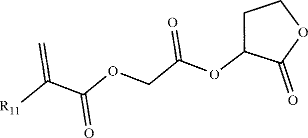

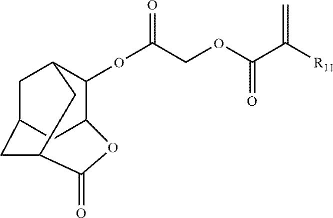

wherein R¹¹ is as described herein.

Additional exemplary lactone-containing monomers include those of formula (5):

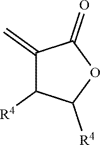

wherein R⁴ is independently hydrogen or C₁₋₃ alkyl. Suitable exemplary monomers of formula (2) include:

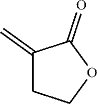

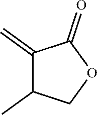

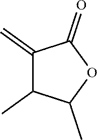

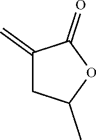

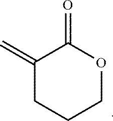

When present in the acid-sensitive polymer, the content of the lactone repeating unit is typically from 5 to 60 mol%, from 20 to 55 mol%, or from 25 to 50 mol% based on total repeating units in the acid-sensitive polymer.

The acid-sensitive polymer may include a base-soluble repeating unit having a pKa of less than or equal to 12. For example, the base-soluble repeating unit can be derived from a monomer of formula (6):

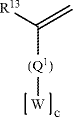

In formula (6), R¹³ may be hydrogen, substituted or unsubstituted C₁₋₁₀ alkyl, or substituted or unsubstituted C₁₋₁₀ fluoroalkyl. Preferably, R¹³ is hydrogen, fluorine, or substituted or unsubstituted C₁₋₅ alkyl, typically methyl. Q¹ may be one or more of substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₃₋₃₀ heteroarylalkyl, or —C(O)—O—. W is a base-soluble group and can be chosen, for example, from: a fluorinated alcohol such as —C(CF₃)₂OH; an amide; an imide; or —NHS(O)₂Y¹, and —C(O)NHC(O)Y¹, where Y¹ is C₁₋₄ perfluoroalkyl or a fluoroalcohol group. In formula (4), c is an integer from 1 to 3.

Non-limiting examples of monomers of formula (6) include:

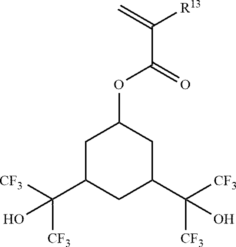

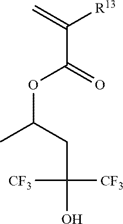

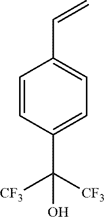

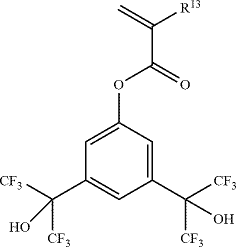

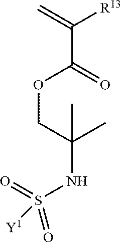

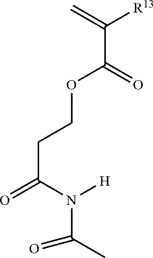

wherein R¹³ and Y¹ are as described above.

When present, the base-soluble repeating unit may be present in the acid-sensitive polymer typically in an amount from 2 to 75 mol%, typically 5 to 25 mol%, more typically 5 to 15 mol%, based on total repeating units in the acid-sensitive polymer.

Suitable acid-sensitive polymers include, for example, the following:

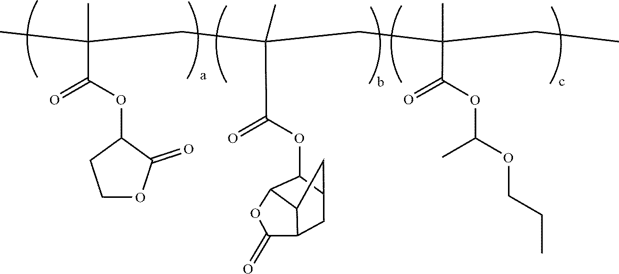

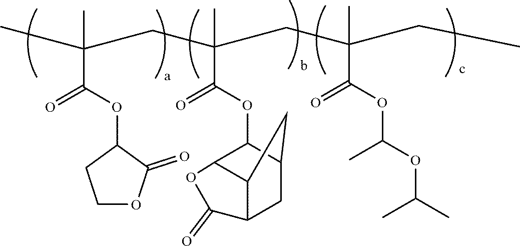

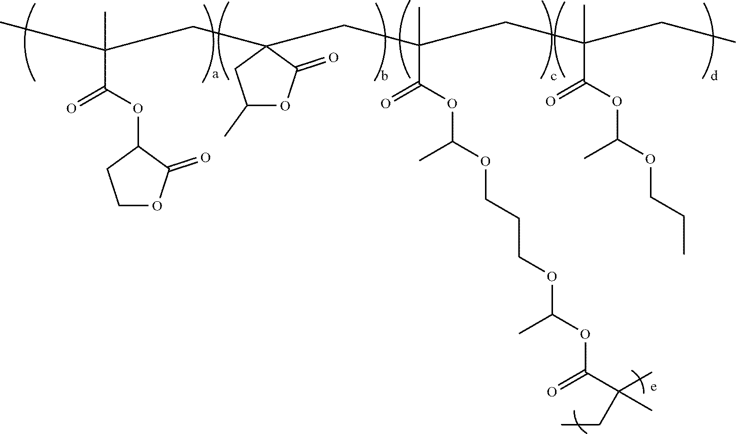

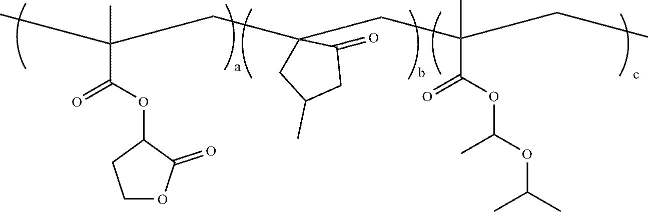

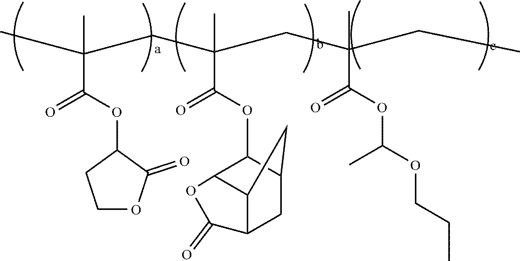

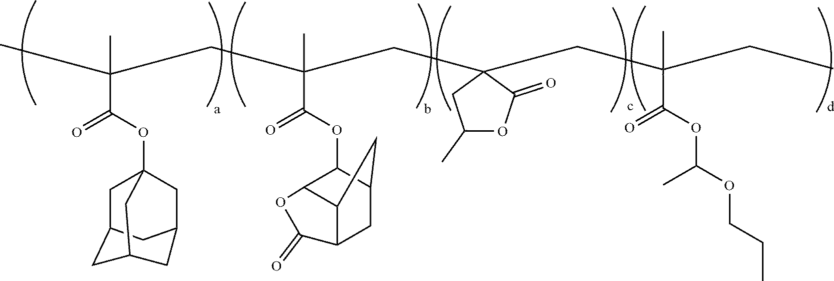

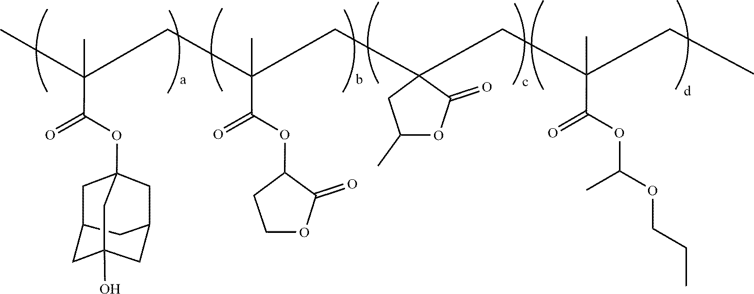

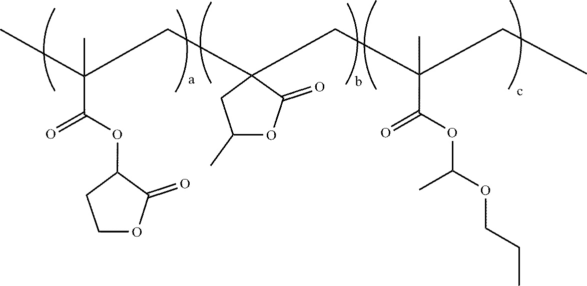

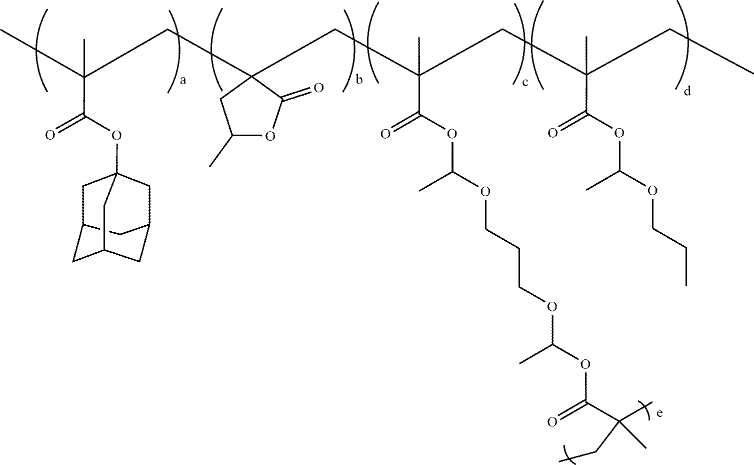

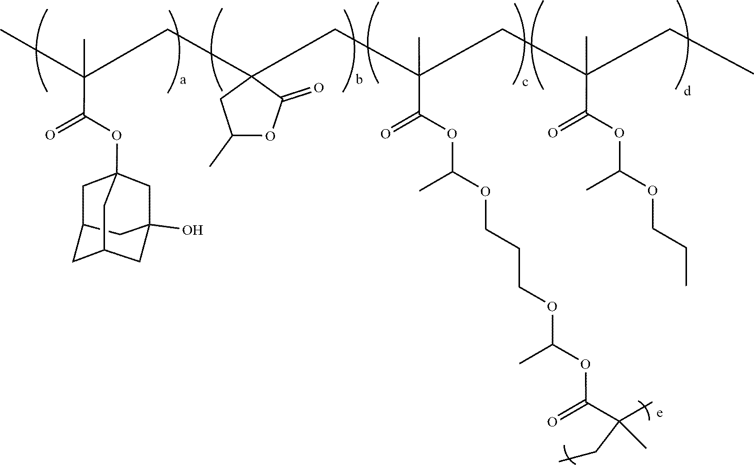

wherein a, b, c, and d each represent the mol% of the associated repeating unit based on 100 mol% of total repeating units in the polymer.

The acid-sensitive polymer typically has a weight average molecular weight (M_{w}) from 1,000 to 50,000 Dalton (Da), preferably from 2,000 to 30,000 Da, more preferably 3,000 to 20,000 Da, and still more preferably from 4,000 to 15,000 Da. The PDI of the polymer is typically from 1.1 to 3, and more typically from 1.1 to 2. Molecular weights are determined by gel permeation chromatography (GPC) using polystyrene standards. The acid-sensitive polymer is typically present in the photoresist composition in an amount from 50 to 95 wt%, more typically from 80 to 95 wt%, based on total solids of the photoresist composition. It will be understood that “total solids” includes the acid-sensitive polymer, PAG, base-labile group-containing material, and other non-solvent components of the photoresist composition.

Suitable polymers of the present invention can be readily prepared based on and by analogy with the procedures described in the examples of the present application, which are readily understood by those of ordinary skill in the art. For example, one or more monomers corresponding to the repeating units described herein may be combined, or fed separately, using suitable solvent(s) and initiator, and polymerized in a reactor. The monomer composition may further include additives, such as a solvent, a polymerization initiator, a curing catalyst (i.e., the acid catalyst), and the like. For example, the polymer may be obtained by polymerization of the respective monomers under any suitable conditions, such as by heating at an effective temperature, irradiation with activating radiation at an effective wavelength, or a combination thereof. In some aspects, the monomer composition further includes a curing agent.

The photoresist compositions further include a material that comprises one or more base-labile groups (a “base-labile material”). As referred to herein, base-labile groups are functional groups that can undergo cleavage reaction to provide polar groups such as hydroxyl, carboxylic acid, sulfonic acid, and the like, in the presence of an aqueous alkaline developer after exposure and post-exposure baking steps. The base-labile group will not react significantly (e.g., will not undergo a bond-breaking reaction) prior to a development step of the photoresist composition that comprises the base-labile group. Thus, for instance, a base-labile group will be substantially inert during pre-exposure soft-bake, exposure, and post-exposure bake steps. By “substantially inert” it is meant that 5% or less, typically 1% or less, of the base-labile groups (or moieties) will decompose, cleave, or react during the pre-exposure soft-bake, exposure, and post-exposure bake steps. The base-labile group is reactive under typical photoresist development conditions using, for example, an aqueous alkaline photoresist developer such as a 0.26 normal (N) aqueous solution of tetramethylammonium hydroxide (TMAH). For example, a 0.26 N aqueous solution of TMAH may be used for single puddle development or dynamic development, e.g., where the 0.26 N TMAH developer is dispensed onto an imaged photoresist layer for a suitable time such as 10 to 120 seconds (s). An exemplary base-labile group is an ester group, typically a fluorinated ester group. Preferably, the base-labile material is substantially not miscible with and has a lower surface energy than the polymer and other solid components of the photoresist composition. When coated on a substrate, the base-labile material can thereby segregate from other solid components of the photoresist composition to a top surface of the formed photoresist layer.

In some aspects, the base-labile material may be a polymeric material, also referred to herein as a base-labile polymer, which may include one or more repeating units comprising one or more base-labile groups. For example, the base-labile polymer may comprise a repeating unit comprising 2 or more base-labile groups that are the same or different. A preferred base-labile polymer includes at least one repeating unit comprising 2 or more base-labile groups, for example a repeating unit comprising 2 or 3 base-labile groups. The base-labile polymer is typically fluorinated.

The base-labile polymer may be a polymer comprising a repeating unit derived from one or more monomers of formula (7A):

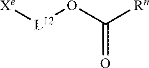

wherein X^{e} is a carbon-carbon unsaturated vinylic group, L12 is a divalent linking group; and Rⁿ is substituted or unsubstituted C1-20 fluoroalkyl, provided that the carbon atom bonded to the carbonyl (C=O) in formula (15A) is substituted with at least one fluorine atom.

Exemplary monomers of formula (7A) include the following:

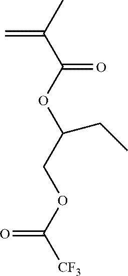 [SMILES: C=C(C)C(=O)OC(CC)COC(=O)C(F)(F)F]

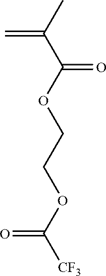

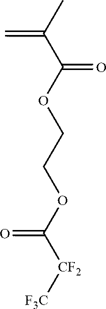 [SMILES: C=C(C)C(=O)OCCOC(=O)C(F)(F)C(F)(F)F]

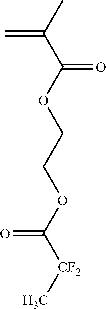

The base-labile polymer may include a repeating unit including two or more base-labile groups. For example, the base-labile polymer can include a repeating unit derived from one or more monomers of formula (7B):

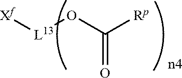

wherein X^{f} is a carbon-carbon unsaturated vinylic group; R^{p} is substituted or unsubstituted C1-20 fluoroalkyl, provided that the carbon atom bonded to the carbonyl (C═O) in formula (15B) is substituted with at least one fluorine atom; L¹³ is a polyvalent linking group including one or more of substituted or unsubstituted C1-20 alkylene, substituted or unsubstituted C3-20 cycloalkylene, —C(O)—, or —C(O)O—; and n4 may be an integer of 2 or greater, for example 2 or 3.

Exemplary monomers of formula (7B) include the following:

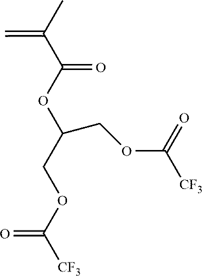 [SMILES: C=C(C)C(=O)OC(COC(=O)C(F)(F)F)COC(=O)C(F)(F)F]

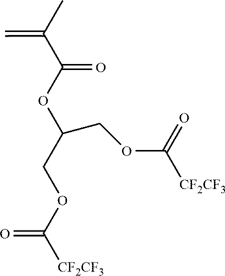

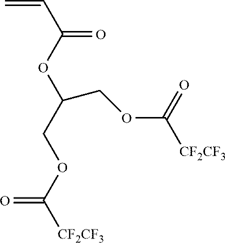

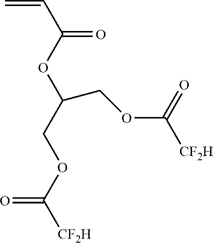 [SMILES: C=CC(=O)OC(COC(=O)C(F)F)COC(=O)C(F)F]

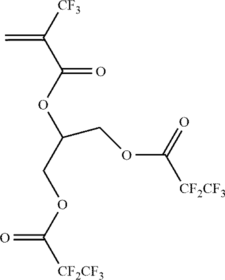

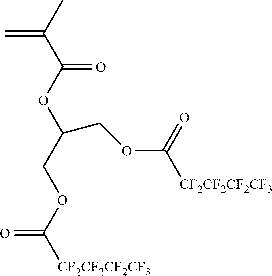

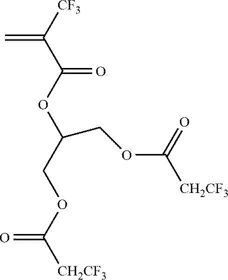

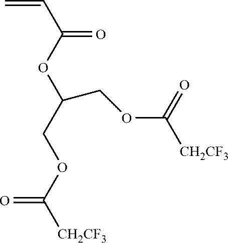

The base-labile polymer may include a repeating unit including one or more base-labile groups. For example, the base-labile polymer can include a repeating unit derived from one or more monomers of formula (7C):

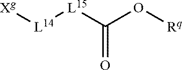

wherein X^{g} and R^{q} are as defined in formula (15A) for X^{e} and Rⁿ, respectively; L¹⁴ is a divalent linking group; and L¹⁵ is substituted or unsubstituted C1-20 fluoroalkylene wherein the carbon atom bonded to the carbonyl (C═O) in formula (7C) is substituted with at least one fluorine atom.

Exemplary monomers of formula (7C) include the following:

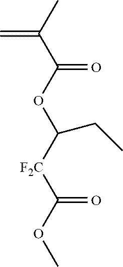 [SMILES: C=C(C)C(=O)OC(CC)C(F)(F)C(=O)OC]

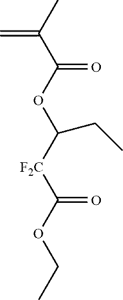 [SMILES: C=C(C)C(=O)OC(CC)C(F)(F)C(=O)OCC]

In some embodiments, a base-labile polymer may comprise one or more base-labile groups and one or more acid-labile groups, such as one or more acid-labile ester moieties (e.g., t-butyl ester) or acid-labile acetal groups. For example, the base-labile polymer may comprise a repeating unit including a base-labile group and an acid-labile group, i.e., wherein both a base-labile group and an acid-labile group are present on the same repeating unit. In another example, the base-labile polymer may comprise a first repeating unit comprising a base-labile group and a second repeating unit comprising an acid-labile group. Preferred photoresists of the invention can exhibit reduced defects associated with a resist relief image formed from the photoresist composition.

The base-labile polymer may be prepared using any suitable methods in the art, including those described herein for the first and second polymers. For example, the base-labile polymer may be obtained by polymerization of the respective monomers under any suitable conditions, such as by heating at an effective temperature, irradiation with actinic radiation at an effective wavelength, or a combination thereof. Additionally, or alternatively, one or more base-labile groups may be grafted onto the backbone of a polymer using suitable methods.

In some aspects, the base-labile material is a single molecule comprising one more base-labile ester groups, preferably one or more fluorinated ester groups. The base-labile materials that are single molecules typically have a MW in the range from 50 to 1,500 Da. Exemplary base-labile materials include the following:

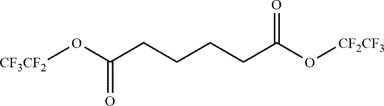

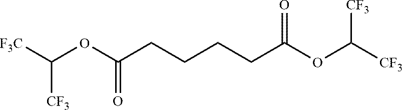 [SMILES: O=C(CCCCC(=O)OC(C(F)(F)F)C(F)(F)F)OC(C(F)(F)F)C(F)(F)F]

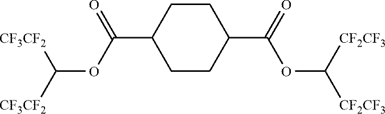

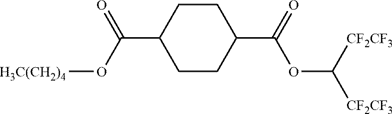

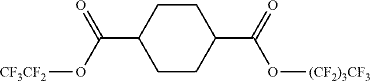

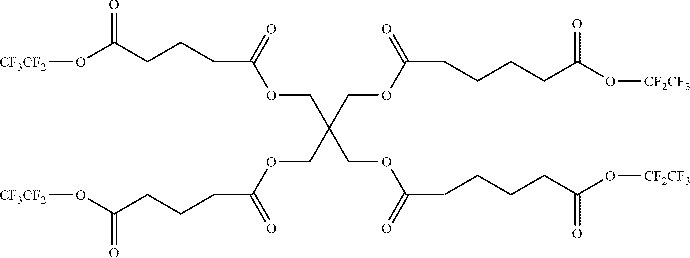

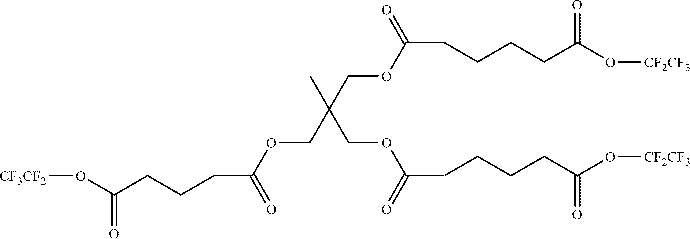

Typically, the base-labile material is present in the photoresist composition in an amount from 1 to 10 wt%, more typically from 3 to 9 wt%, based on total solids of the photoresist composition.

The photoresist compositions include a photoacid generator (PAG) compound that is free of fluorine and generates an acid having a pKa of -2 or greater, for example, from -2 to 3. The acid generated by the PAG should have a strength sufficient to cause deprotection of acid-labile groups on the polymer during photoresist processing, typically during post-exposure baking. The PAG is typically of non-polymeric form, but may be in polymeric form, for example, present in a polymerized repeating unit of the acid-sensitive polymer or as part of a different polymer. Suitable PAGs can generate an acid that, during post-exposure bake, causes decomposition of the acid-labile ester acetal groups present on the photoresist polymer in exposed regions of the photoresist layer.

Particularly suitable PAGs are ionic of the formula G⁺A⁻, wherein G⁺ is an organic cation and A⁻ is an organic anion, the conjugate acid of which has a pKa of -2 or greater, for example, from -2 to 3. Organic cations include, for example, iodonium cations substituted with two alkyl groups, aryl groups, or a combination of alkyl and aryl groups; and sulfonium cations substituted with three alkyl groups, aryl groups, or a combination of alkyl and aryl groups. In some embodiments, G⁺ is an iodonium cation substituted with two alkyl groups, aryl groups, or a combination of alkyl and aryl groups; or a sulfonium cation substituted with three alkyl groups, aryl groups, or a combination of alkyl and aryl groups. In some embodiments, G⁺ may be one or more of a substituted sulfonium cation having the formula (8A) or an iodonium cation having the formula (8B):

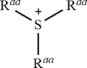

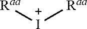

wherein, each R^{aa} is independently a C₁₋₂₀ alkyl group, a C₁₋₂₀ fluoroalkyl group, a C₃₋₂₀ cycloalkyl group, a C₃₋₂₀ fluorocycloalkyl group, a C₂₋₂₀ alkenyl group, a C₂₋₂₀ fluoroalkenyl group, a C₆₋₃₀ aryl group, a C₆₋₃₀ fluoroaryl group, C₆₋₃₀ iodoaryl group, a C₄₋₃₀ heteroaryl group, a C₇₋₂₀ arylalkyl group, a C₇₋₂₀ fluoroarylalkyl group, a C₅₋₃₀ heteroarylalkyl group, or a C₅₋₃₀ fluoroheteroarylalkyl group, each of which is substituted or unsubstituted, wherein each R^{aa} is either separate or connected to another group R^{aa} via a single bond or a divalent linking group to form a ring. Each R^{aa} optionally may include as part of its structure one or more groups selected from —O—, —C(O)—, —C(O)O—, —C_{1—12} hydrocarbylene—, —O(C_{1—12} hydrocarbylene)—, —C(O)O(C_{1—12} hydrocarbylene)—, and —C(O)O(C_{1—12} hydrocarbylene)O—. Each R^{aa} independently may optionally comprise an acid-decomposable group chosen, for example, from tertiary alkyl ester groups, secondary or tertiary aryl ester groups, secondary or tertiary ester groups having a combination of alkyl and aryl groups, tertiary alkoxy groups, acetal groups, or ketal groups. Suitable divalent linking groups for connection of R^{aa} groups include, for example, —O—, —S—, —Te—, —Se—, —C(O)—, —C(S)—, —C(Te)—, or —C(Se)—, substituted or unsubstituted C₁₋₅ alkylene, and combinations thereof.

Exemplary sulfonium cations of formula (8A) include the following:

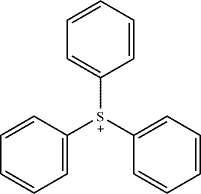 [SMILES: c1ccc([S+](c2ccccc2)c2ccccc2)cc1]

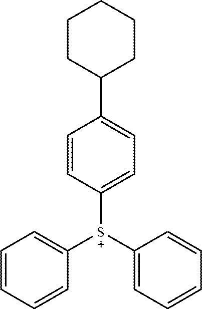 [SMILES: c1ccc([S+](c2ccccc2)c2ccc(C3CCCCC3)cc2)cc1]

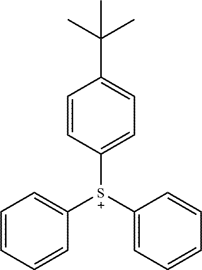 [SMILES: CC(C)(C)c1ccc([S+](c2ccccc2)c2ccccc2)cc1]

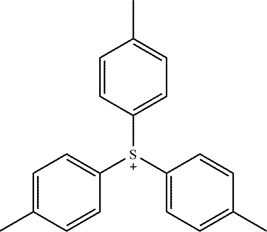

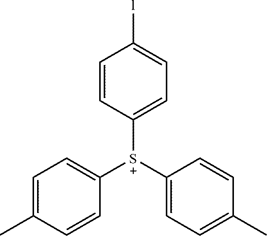

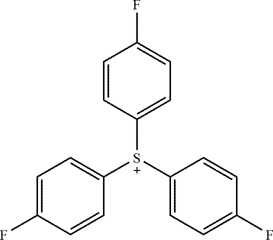 [SMILES: Fc1ccc([S+](c2ccc(F)cc2)c2ccc(F)cc2)cc1]

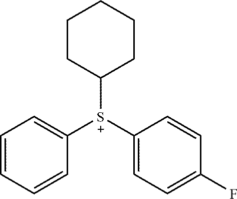 [SMILES: Fc1ccc([S+](c2ccccc2)C2CCCCC2)cc1]

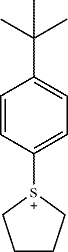

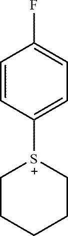 [SMILES: Fc1ccc([S+]2CCCCC2)cc1]

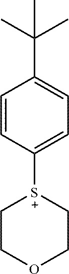 [SMILES: CC(C)(C)c1ccc([S+]2CCOCC2)cc1]

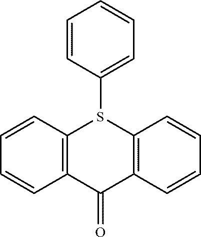

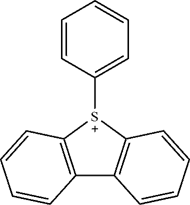 [SMILES: c1ccc(-[s+]2c3ccccc3c3ccccc32)cc1]

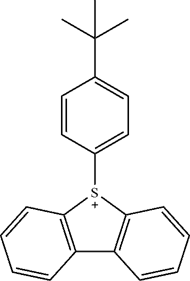 [SMILES: CC(C)(C)c1ccc(-[s+]2c3ccccc3c3ccccc32)cc1]

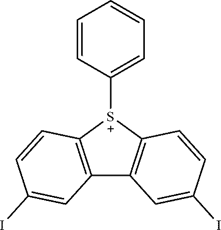 [SMILES: Ic1ccc2c(c1)c1cc(I)ccc1[s+]2-c1ccccc1]

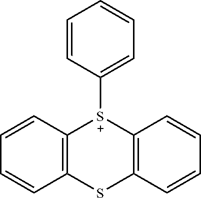 [SMILES: c1ccc([S+]2c3ccccc3Sc3ccccc32)cc1]

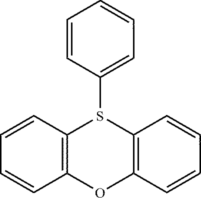

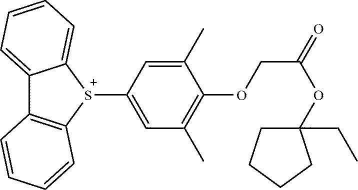 [SMILES: CCC1(OC(=O)COc2c(C)cc(-[s+]3c4ccccc4c4ccccc43)cc2C)CCCC1]

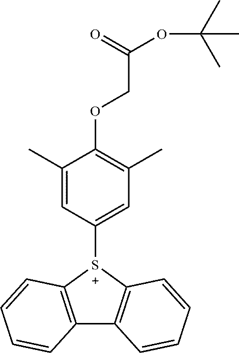 [SMILES: Cc1cc(-[s+]2c3ccccc3c3ccccc32)cc(C)c1OCC(=O)OC(C)(C)C]

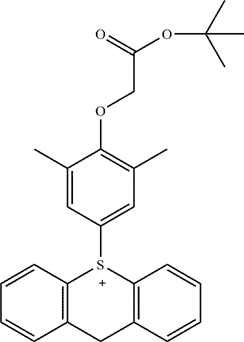 [SMILES: Cc1cc([S+]2c3ccccc3Cc3ccccc32)cc(C)c1OCC(=O)OC(C)(C)C]

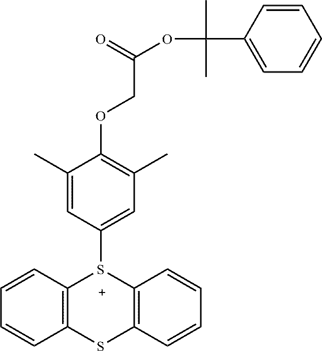 [SMILES: Cc1cc([S+]2c3ccccc3Sc3ccccc32)cc(C)c1OCC(=O)OC(C)(C)c1ccccc1]

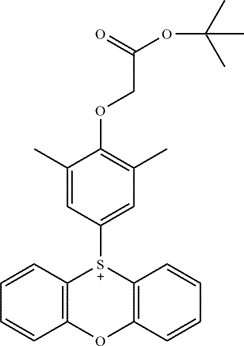 [SMILES: Cc1cc([S+]2c3ccccc3Oc3ccccc32)cc(C)c1OCC(=O)OC(C)(C)C]

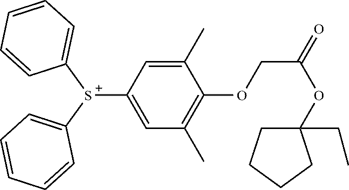 [SMILES: CCC1(OC(=O)COc2c(C)cc([S+](c3ccccc3)c3ccccc3)cc2C)CCCC1]

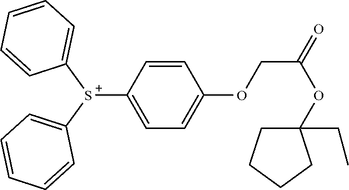 [SMILES: CCC1(OC(=O)COc2ccc([S+](c3ccccc3)c3ccccc3)cc2)CCCC1]

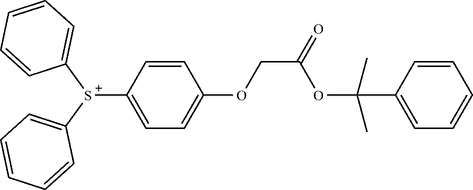 [SMILES: CC(C)(OC(=O)COc1ccc([S+](c2ccccc2)c2ccccc2)cc1)c1ccccc1]

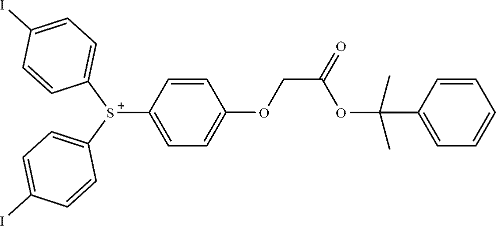 [SMILES: CC(C)(OC(=O)COc1ccc([S+](c2ccc(I)cc2)c2ccc(I)cc2)cc1)c1ccccc1]

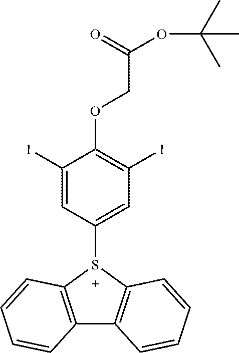 [SMILES: CC(C)(C)OC(=O)COc1c(I)cc(-[s+]2c3ccccc3c3ccccc32)cc1I]

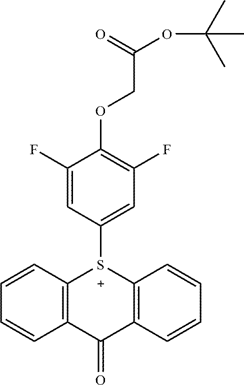 [SMILES: CC(C)(C)OC(=O)COc1c(F)cc(-[s+]2c3ccccc3c(=O)c3ccccc32)cc1F]

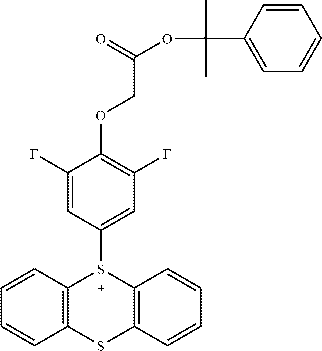 [SMILES: CC(C)(OC(=O)COc1c(F)cc([S+]2c3ccccc3Sc3ccccc32)cc1F)c1ccccc1]

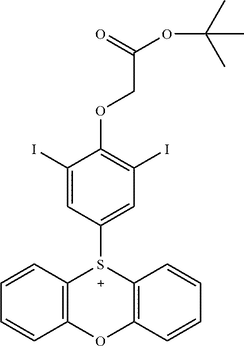 [SMILES: CC(C)(C)OC(=O)COc1c(I)cc([S+]2c3ccccc3Oc3ccccc32)cc1I]

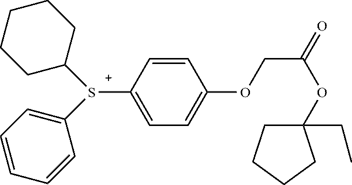 [SMILES: CCC1(OC(=O)COc2ccc([S+](c3ccccc3)C3CCCCC3)cc2)CCCC1]

Exemplary iodonium cations of formula (8B) include the following:

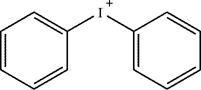 [SMILES: c1ccc([I+]c2ccccc2)cc1]

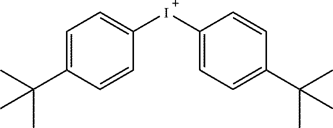 [SMILES: CC(C)(C)c1ccc([I+]c2ccc(C(C)(C)C)cc2)cc1]

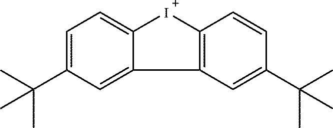 [SMILES: CC(C)(C)c1ccc2c(c1)-c1cc(C(C)(C)C)ccc1[I+]2]

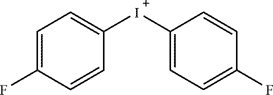 [SMILES: Fc1ccc([I+]c2ccc(F)cc2)cc1]

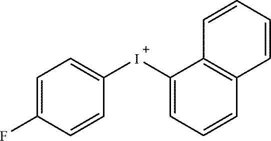 [SMILES: Fc1ccc([I+]c2cccc3ccccc23)cc1]

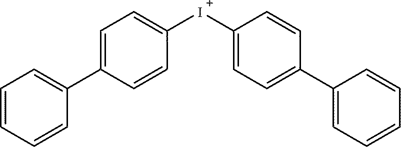 [SMILES: c1ccc(-c2ccc([I+]c3ccc(-c4ccccc4)cc3)cc2)cc1]

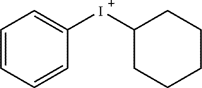 [SMILES: c1ccc([I+]C2CCCCC2)cc1]

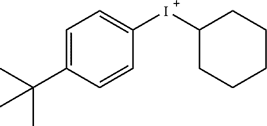 [SMILES: CC(C)(C)c1ccc([I+]C2CCCCC2)cc1]

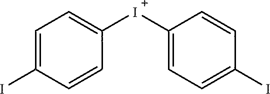 [SMILES: Ic1ccc([I+]c2ccc(I)cc2)cc1]

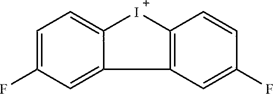 [SMILES: Fc1ccc2c(c1)-c1cc(F)ccc1[I+]2]

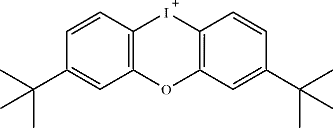 [SMILES: CC(C)(C)c1ccc2c(c1)Oc1cc(C(C)(C)C)ccc1[I+]2]

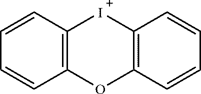 [SMILES: c1ccc2c(c1)Oc1ccccc1[I+]2]

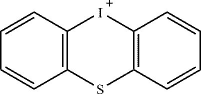 [SMILES: c1ccc2c(c1)Sc1ccccc1[I+]2]

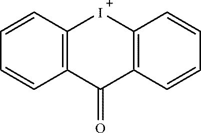 [SMILES: O=C1c2ccccc2[I+]c2ccccc21]

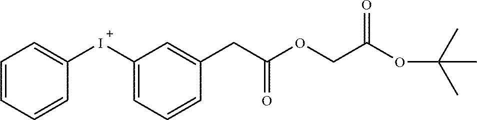 [SMILES: CC(C)(C)OC(=O)COC(=O)Cc1cccc([I+]c2ccccc2)c1]

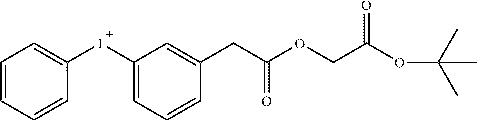 [SMILES: CC(C)(C)OC(=O)COC(=O)Cc1cccc([I+]c2ccccc2)c1]

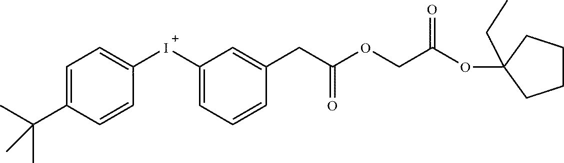 [SMILES: CCC1(OC(=O)COC(=O)Cc2cccc([I+]c3ccc(C(C)(C)C)cc3)c2)CCCC1]

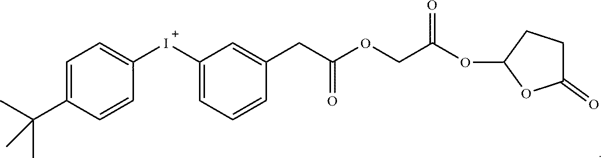

Suitable onion salt PAG anions include a group chosen, for example, from sulfonate and sulfonyl groups. Suitable sulfonate anions include both aromatic and non-aromatic sulfonates that are free of fluorine. Exemplary suitable anions having a sulfonate group include the following:

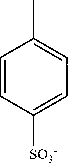

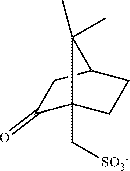

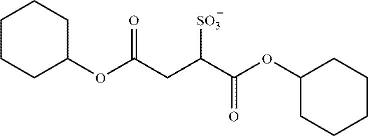

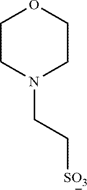

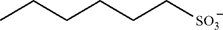

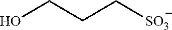

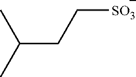

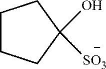

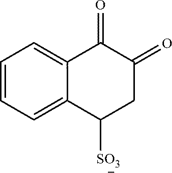

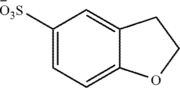

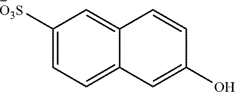

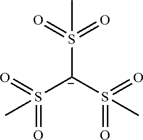

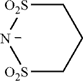

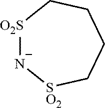 [SMILES: O=S1(=O)CCCCS(=O)(=O)[N-]1]

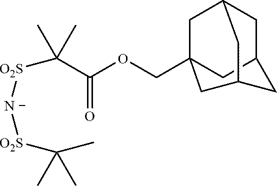 [SMILES: CC(C)(C)S(=O)(=O)[N-]S(=O)(=O)C(C)(C)C(=O)OCC12CC3CC(CC(C3)C1)C2]

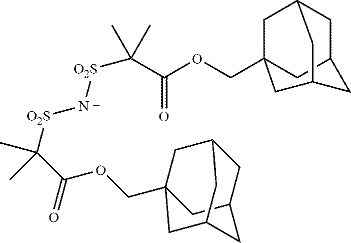 [SMILES: CC(C)(C(=O)OCC12CC3CC(CC(C3)C1)C2)S(=O)(=O)[N-]S(=O)(=O)C(C)(C)C(=O)OCC12CC3CC(CC(C3)C1)C2]

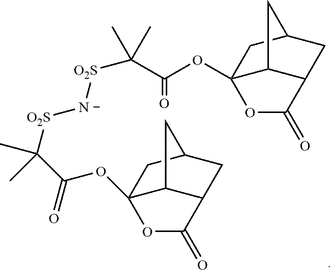

The photoresist composition may optionally comprise a plurality of PAGs. Typically, the photoacid generator is present in the photoresist composition in an amount from 3 to 65 wt%, more typically from 5 to 55 wt%, and still more typically from 8 to 30 wt%, based on total solids of the photoresist composition.

The photoresist compositions further include a solvent for dissolving the components of the composition and facilitating its coating on a substrate. Preferably, the solvent is an organic solvent conventionally used in the manufacture of electronic devices. Suitable solvents include, for example: aliphatic hydrocarbons such as hexane and heptane; aromatic hydrocarbons such as toluene and xylene; halogenated hydrocarbons such as dichloromethane, 1,2-dichloroethane, and 1-chlorohexane; alcohols such as methanol, ethanol, 1-propanol, iso-propanol, tert-butanol, 2-methyl-2-butanol, and 4-methyl-2-pentanol; propylene glycol monomethyl ether (PGME), ethers such as diethyl ether, tetrahydrofuran, 1,4-dioxane, and anisole; ketones such as acetone, methyl ethyl ketone, methyl iso-butyl ketone, 2-heptanone, and cyclohexanone (CHO); esters such as ethyl acetate, n-butyl acetate, propylene glycol monomethyl ether acetate (PGMEA), ethyl lactate (EL), hydroxyisobutyrate methyl ester (HBM), and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; water; and combinations thereof. Of these, preferred solvents are PGME, PGMEA, EL, GBL, HBM, CHO, and combinations thereof. The total solvent content (i.e., cumulative solvent content for all solvents) in the photoresist compositions is typically from 40 to 99 wt%, for example, from 70 to 99 wt%, or from 85 to 99 wt%, based on total weight of the photoresist composition. The desired solvent content will depend, for example, on the desired thickness of the coated photoresist layer and coating conditions.

The photoresist composition may further include one or more additional, optional additives. Such optional additives may include, for example, actinic and contrast dyes, anti-striation agents, plasticizers, speed enhancers, sensitizers, photo-decomposable quenchers (also known as photo-decomposable bases), basic quenchers, surfactants, and the like, or combinations thereof. If present, the optional additives are typically present in the photoresist compositions in an amount of from 0.01 to 10 wt%, based on total solids of the photoresist composition.

Photo-decomposable quenchers (PDQs) generate a weak acid upon irradiation. The generated acid is not sufficiently strong to decompose the ester acetal acid-labile groups on the acid-sensitive polymer. The generated acid of the PDQ is thus weaker (greater pKa) than the acid generated by the PAG compound. Typically, the pKa of the PDQ generated acid is greater than 3, for example, from 3 to 6. Exemplary photo-decomposable quenchers include, for example, photo-decomposable cations, and preferably those also useful for preparing strong acid generator compounds but paired with an anion of a weak acid (pKa > 3) such as, for example, a C1-20 carboxylic acid. Exemplary carboxylic acids include formic acid, acetic acid, propionic acid, tartaric acid, succinic acid, cyclohexanecarboxylic acid, benzoic acid, salicylic acid, and the like. In a preferred embodiment, the photo-decomposable quencher is a photo-decomposable organic zwitterion compound such as diphenyliodonium-2-carboxylate.

Exemplary basic quenchers include, for example: linear aliphatic amines such as tributylamine, trioctylamine, triisopropanolamine, tetrakis(2-hydroxypropyl)ethylenediamine:n-tert-butyldiethanolamine, tris(2-acetoxy-ethyl) amine, 2,2′,2″,2‴-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N1,N1,N3,N3-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

Exemplary surfactants include fluorinated and non-fluorinated surfactants and can be ionic or non-ionic, with non-ionic surfactants being preferable. Exemplary fluorinated non-ionic surfactants include perfluoro C4 surfactants such as FC-4430 and FC-4432 surfactants, available from 3M Corporation; and fluorodiols such as POLYFOX PF-636, PF-6320, PF-656, and PF-6520 fluorosurfactants from Omnova. In an aspect, the photoresist composition may further include a surfactant polymer including a fluorine-containing repeating unit.

Patterning methods using the photoresist compositions of the invention will now be described. Suitable substrates on which the photoresist compositions can be coated include electronic device substrates. A wide variety of electronic device substrates may be used in the present invention, such as: semiconductor wafers; polycrystalline silicon substrates; packaging substrates such as multichip modules; flat panel display substrates; substrates for light emitting diodes (LEDs) including organic light emitting diodes (OLEDs); and the like, with semiconductor wafers being typical. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Suitable substrates may be in the form of wafers such as those used in the manufacture of integrated circuits, optical sensors, flat panel displays, integrated optical circuits, and LEDs. Such substrates may be any suitable size. Typical wafer substrate diameters are 200 to 300 millimeters (mm), although wafers having smaller and larger diameters may be suitably employed according to the present invention. The substrates may include one or more layers or structures which may optionally include active or operable portions of devices being formed.

Typically, one or more lithographic layers such as a hardmask layer, for example, a spin-on-carbon (SOC), amorphous carbon, or metal hardmask layer, a CVD layer such as a silicon nitride (SiN), a silicon oxide (SiO), or silicon oxynitride (SiON) layer, an organic or inorganic underlayer such as a bottom antireflective coating (BARC) layer, or combinations thereof, are provided on an upper surface of the substrate prior to coating a photoresist composition of the present invention. Such layers, together with an overcoated photoresist layer, form a lithographic material stack.

Optionally, a layer of an adhesion promoter may be applied to the substrate surface prior to coating the photoresist compositions. If an adhesion promoter is desired, any suitable adhesion promoter for polymer films may be used, such as silanes, typically organosilanes such as trimethoxyvinylsilane, triethoxyvinylsilane, hexamethyldisilazane, or an aminosilane coupler such as gammaaminopropyltriethoxysilane. Particularly suitable adhesion promoters include those sold under the AP 3000, AP 8000, and AP 9000S designations, available from DuPont Electronics & Imaging (Marlborough, Massachusetts).

The photoresist composition may be coated on the substrate by any suitable method, including spin coating, spray coating, dip coating, doctor blading, or the like. For example, applying the layer of photoresist may be accomplished by spin coating the photoresist in solvent using a coating track, in which the photoresist is dispensed on a spinning wafer. During dispensing, the wafer is typically spun at a speed of up to 4,000 rotations per minute (rpm), for example, from 200 to 3,000 rpm, for example, 1,000 to 2,500 rpm, for a period of from 15 to 120 seconds to obtain a layer of the photoresist composition on the substrate. It will be appreciated by those skilled in the art that the thickness of the coated layer may be adjusted by changing the spin speed and/or the solids content of the composition. A photoresist layer formed from the compositions of the invention typically has a dried layer thickness of from 10 to 3000 nanometers (nm), more typically from 15 to 500 nm, from 20 to 200 nm, or from 50 to 150 nm.

The photoresist composition is typically next soft-baked to minimize the solvent content in the layer, thereby forming a tack-free coating and improving adhesion of the layer to the substrate. The soft-bake is performed, for example, on a hotplate or in an oven, with a hotplate being typical. The soft-bake temperature and time will depend, for example, on the particular photoresist composition and thickness. The soft-bake temperature is typically from 90 to 170° C., for example, from 110 to 150° C. The soft-bake time is typically from 10 seconds to 20 minutes, for example, from 1 minute to 10 minutes, or from 1 minute to 5 minutes. The soft-bake temperature and time can be readily determined by one of ordinary skill in the art based on the components of the composition.

The photoresist layer is next pattern-wise exposed to activating radiation to create a difference in solubility between exposed and unexposed regions. It may be desirable to include a delay between soft-bake and exposure. Suitable delay times include, for example from 5 seconds to 30 minutes or from 1 to 5 minutes. Reference herein to exposing a photoresist composition to radiation that is activating for the composition indicates that the radiation is capable of forming a latent image in the photoresist composition. The exposure is typically conducted through a patterned photomask that has optically transparent and optically opaque regions corresponding to regions of the resist layer to be exposed and unexposed, respectively. Such exposure may, alternatively, be conducted without a photomask in a direct writing method, typically used for e-beam lithography. The activating radiation typically has a wavelength of sub-400 nm, sub-300 nm or sub-200 nm, such as 248 nm (KrF), 193 nm (ArF), and 13.5 nm (extreme ultraviolet, EUV) wavelengths or e-beam lithography, with 193 nm being typical. The methods find use in immersion or dry (non-immersion) lithography techniques. The exposure energy is typically from 1 to 200 millijoules per square centimeter (mJ/cm²), preferably 10 to 100 mJ/cm² and more preferably 20 to 50 mJ/cm², dependent upon the exposure tool and components of the photoresist composition. In a preferred aspect, the activating radiation is 193 nm (ArF), with 193 nm immersion lithography being particularly preferred.

Following exposure of the photoresist layer, a post-exposure bake (PEB) of the exposed photoresist layer is performed. Suitable PEB times include, for example from 5 seconds to 30 minutes or from 1 to 5 minutes. The PEB can be conducted, for example, on a hotplate or in an oven, with a hotplate being typical. Conditions for the PEB will depend, for example, on the particular photoresist composition and layer thickness. The PEB is typically conducted at a temperature of from 80 to 150° C., and a time of from 30 to 120 seconds. A latent image defined by the polarity-switched (exposed regions) and unswitched regions (unexposed regions) is formed in the photoresist layer. This polarity-switching results from photoacid-catalyzed deprotection of the polymer’s ester acetal groups, thereby forming carboxylic acid groups on the polymer in the exposed regions.

The exposed photoresist layer is next developed with a suitable developer to selectively remove those regions of the layer that are soluble in the developer while the remaining insoluble regions form the resulting photoresist pattern relief image. In the case of a positive-tone development (PTD) process, the exposed regions of the photoresist layer are removed during development and unexposed regions remain. Conversely, in a negative-tone development (NTD) process, the exposed regions of the photoresist layer remain, and unexposed regions are removed during development. Application of the developer may be accomplished by any suitable method such as described above with respect to application of the photoresist composition, with spin coating being typical. The development time is for a period effective to remove the soluble regions of the photoresist, with a time of from 5 to 60 seconds being typical. Development is typically conducted at room temperature.

Suitable developers for a PTD process include aqueous base developers, for example, quaternary ammonium hydroxide solutions such as tetramethylammonium hydroxide (TMAH), preferably 0.26 normal (N) TMAH, tetraethylammonium hydroxide, tetrabutylammonium hydroxide, sodium hydroxide, potassium hydroxide, sodium carbonate, potassium carbonate, and the like. Suitable developers for an NTD process are organic solvent-based, meaning the cumulative content of organic solvents in the developer is 50 wt% or more, typically 95 wt% or more, 95 wt% or more, 98 wt% or more, or 100 wt%, based on total weight of the developer. Suitable organic solvents for the NTD developer include, for example, those chosen from ketones, esters, ethers, hydrocarbons, and mixtures thereof. The developer is typically n-butyl acetate or 2-heptanone.

A coated substrate may be formed from the photoresist compositions of the invention. Such a coated substrate includes: (a) a substrate having one or more layers to be patterned on a surface thereof; and (b) a layer of the photoresist composition over the one or more layers to be patterned.

The photoresist pattern may be used, for example, as an etch mask, thereby allowing the pattern to be transferred to one or more sequentially underlying layers by known etching techniques, typically by dry-etching such as reactive ion etching. The photoresist pattern may, for example, be used for pattern transfer to an underlying hardmask layer which, in turn, is used as an etch mask for pattern transfer to one or more layers below the hardmask layer. If the photoresist pattern is not consumed during pattern transfer, it may be removed from the substrate by known techniques, for example, oxygen plasma ashing. The photoresist compositions may, when used in one or more such patterning processes, be used to fabricate semiconductor devices such as memory devices, processor chips (CPUs), graphics chips, optoelectronic chips, LEDs, OLEDs, as well as other electronic devices.

The following non-limiting examples are illustrative of the invention.

### EXAMPLES

### Polymer Synthesis

The following monomers were used to synthesize polymers according to the procedures described below:

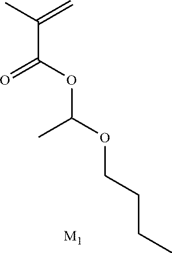

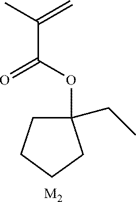

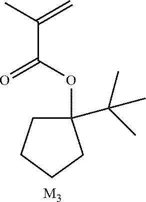

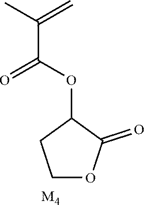

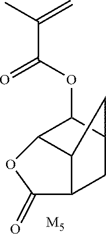

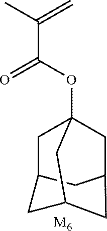

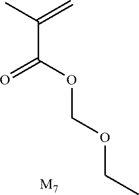

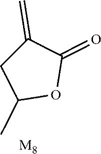

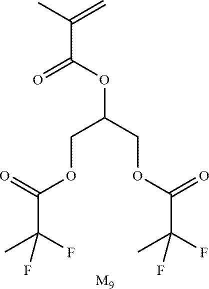

### Example 1 (Polymer P1)

A feed solution was prepared by combining 36.69 g propylene glycol monomethyl ether acetate (PGMEA), 11.95 g monomer M1, 10.92 g monomer M2, 7.13 g monomer M3 and 1.59 g Wako V-601 initiator in a container, and agitating the mixture to dissolve the components. 15.93 g PGMEA was introduced into a reaction vessel and the vessel was purged with nitrogen for 30 minutes. The reaction vessel was next heated to 80° C. with agitation. The monomer feed solution was then introduced into the reaction vessel and fed over a period of 4 hours. The initiator feed solution was then introduced into the reaction vessel and fed over a period of 3.5 hours. The reaction vessel was maintained at 80° C. for an additional three hours with agitation. The reaction mixture was then heated at 80° C. for an additional 30 minutes followed by cooling to room temperature. The polymer was precipitated by dropwise addition of the reaction mixture into methanol (10x, v/v) collected by filtration, and dried in vacuo. Polymer P1 was obtained as a white solid powder.

### Examples 2-8 (Polymers P2-P8)

Polymers P2-P8 were synthesized with a procedure similar to that used for Polymer P1. For each of the polymers, the structural units, weight average molecular weight, and polydispersity PDI (Mw/Mn) are shown in Tables 1 and 2.

### Example 9 (Polymer API)

A monomer solution was prepared by combining 192.00 grams (g) of propylene glycol monomethyl ether acetate (PGMEA), 133.2 g of monomer M9 and 8.51 g of monomer M2, in a flask and agitating the resulting mixture to dissolve the components. Separately, an initiator solution was prepared by combining 10.72 g of PGMEA and 6.2 g of V601 initiator (Wako Chemical) in a flask. 20.05 g PGMEA was introduced into a reaction vessel and the vessel was purged with nitrogen for 30 minutes. The reaction vessel was next heated to 95° C. with agitation. The monomer solution and initiator solutions were then introduced as separate feeds into the reaction vessel over a period of 2.5 hours. Upon completion of the 2.5 hours, the reaction vessel was maintained at 95° C. for an additional 3 hours with agitation and was then allowed to cool to room temperature. Polymer AP1 was obtained.

TABLE 1

| Example | Polymer | Monomers (mol%) | | | | | | | | | Mw/Mₙ (kDa) |
|---|---|---|---|---|---|---|---|---|---|---|---|
| | | M1 | M2 | M3 | M4 | M5 | M6 | M7 | M8 | M9 | |
| 1 | P1 | 40 | | | 40 | 20 | | | | | 9.98/5.43 |
| 2 | P2 | | 40 | | 40 | 20 | | | | | 6.21/3.82 |
| 3 | P3 | 10 | 30 | | 40 | 20 | | | | | 10.4/5.26 |
| 4 | P4 | 10 | | 30 | 40 | 20 | | | | | 9.00/4.70 |
| 5 | P5 | 40 | | | 40 | 15 | 5 | | | | 9.47/5.39 |
| 6 | P6 | 30 | | 10 | 40 | 20 | | | | | 9.18/4.89 |
| 7 | P7 | | | | 40 | | 5 | 40 | 15 | | 7.50/4.64 |
| 8 | P8 | | | | 40 | | | 40 | 20 | | 8.18/4.40 |
| 9 | AP1 | | 6 | | | | | | | 94 | 9.66/6.19 |

Mol% of polymerized units of monomers is based on total polymerized units of the polymer.

### Photoresist Composition Preparation

Photoresist compositions were prepared by dissolving solid components in solvents using the materials and amounts set forth in Table 2. The resulting mixtures, made on a 30-100 g scale, were shaken on a mechanical shaker for from 3 to 24 hours and then filtered through a PTFE disk-shaped filter having a 0.2 micron pore size.

TABLE 2

| Example | Photoresist Composition | Matrix Polymer | Additive Polymer | PAG | PDQ | Solvent | |
|---|---|---|---|---|---|---|---|
| 10 | PR1 | P1 (2.57) | AP1 (0.09) | PAG1 (0.38) | PDQ1 (0.05) | S1 (33.9) | S2 (63.1) |
| 11 (Comp) | PR2 | P2 (2.57) | AP1 (0.09) | PAG1 (0.38) | PDQ1 (0.05) | S1 (33.9) | S2 (63.1) |
| 12 (Comp) | PR3 | P3 (2.57) | AP1 (0.09) | PAG1 (0.38) | PDQ1 (0.05) | S1 (33.9) | S2 (63.1) |
| 13 (Comp) | PR4 | P4 (2.57) | AP1 (0.09) | PAG1 (0.38) | PDQ1 (0.05) | S1 (33.9) | S2 (63.1) |
| 14 | PR5 | P5 (2.56) | AP1 (0.09) | PAG1 (0.36) | PDQ1 (0.09) | S1 (33.9) | S2 (63.0) |
| 15 (Comp) | PR6 | P6 (2.56) | AP1 (0.09) | PAG1 (0.36) | PDQ1 (0.09) | S1 (33.9) | S2 (63.0) |
| 16 | PR7 | P7 (2.47) | AP1 (0.09) | PAG2 (0.45) | PDQ1 (0.09) | S1 (33.9) | S2 (63.0) |
| 17 | PR8 | P8 (2.47) | AP1 (0.09) | PAG2 (0.45) | PDQ1 (0.09) | S1 (33.9) | S2 (63.0) |

All amounts provided as weight percent (wt%) based on total photoresist composition.

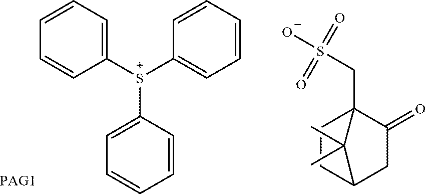

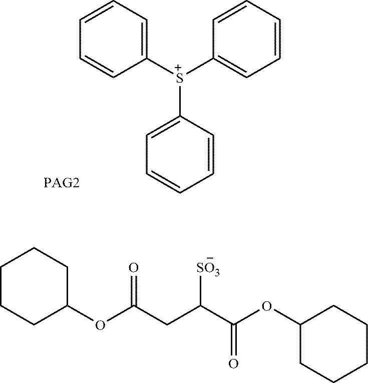

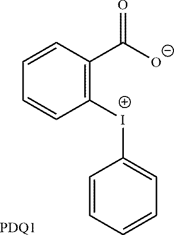

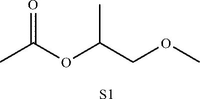

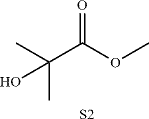

### Lithographic Evaluation

300 mm silicon wafers were spin-coated with AR™40A antireflectant (DuPont Electronics & Industrial) using a cure temperature of 205° C. for 60 seconds to form a first BARC layer having a thickness of 800 Å. The wafers were then spin-coated with AR™104 antireflectant (DuPont Electronics &Imaging) using a cure temperature of 175° C. for 60 seconds to form a second BARC layer having a thickness of 400 Å. The wafers were then spin-coated with a respective photoresist composition SHOWN IN Table 3 and soft-baked at 95° C. for 60 seconds to provide a photoresist layer having a thickness of 900 Å. The BARC and photoresist layers were coated with a TEL Clean Track Lithius coating tool. The wafers were exposed at various doses using an ASML 1900i immersion scanner (1.35 NA, 0.90/0.988 inner/outer sigma, dipole illumination with 35 Y polarization) using a mask having 1:1 line-space patterns (28 nm linewidth/56 nm pitch or 45 nm linewidth/90 nm pitch). The exposed wafers were post-exposure baked at 80° C. for 60 seconds and developed with a 0.26 N aqueous TMAH solution for 12 seconds. The wafers were then rinsed with DI water and spun dry to form photoresist patterns. CD linewidth measurements of the formed patterns were made using a Hitachi High Technologies Co. CG4000 CD-SEM. Esize, which is the exposure dose at which the pattern CD is equal to the CD of the mask pattern, was also determined. LWR was determined using a 3-sigma value from the distribution of a total of 100 arbitrary points of linewidth measurements. The results are shown in Table 3.

TABLE 3

| Example | Photoresist Composition | PEB T (°C) | LW/Pitch (nm) | Esize | LWR |
|---|---|---|---|---|---|
| 18 | PR1 | 80 | 45/90 | 16.8 | 3.11 |
| 19 (Comp) | PR2 | 80 | 45/90 | NP | NP |
| 20 (Comp) | PR3 | 80 | 45/90 | NP | NP |
| 21 (Comp) | PR4 | 80 | 45/90 | NP | NP |
| 22 | PR5 | 80 | 38/76 | 32.2 | 2.40 |
| 23 (Comp) | PR6 | 80 | 38/76 | NP | NP |
| 24 | PR7 | 80 | 38/76 | 32.6 | 2.36 |
| 25 | PR8 | 80 | 38/76 | 28.8 | 2.33 |

1. A photoresist composition, comprising:
an acid-sensitive polymer comprising a repeating unit comprising an ester acetal group, wherein the acid-sensitive polymer is free of tertiary alkyl ester groups and is substantially free of aromatic groups;
a material comprising a base-labile group;
a photoacid generator compound that is free of fluorine which generates an acid having a pKa of -2 or greater, and wherein the photoresist composition is free of photoacid generators that generate an acid having a pKa of less than -2;
and a solvent.

2. The photoresist composition of claim 1, wherein the ester acetal group is of the formula (1) 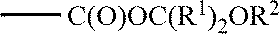
wherein: R¹ is independently hydrogen, fluorine, C₁₋₂₀ alkyl, monocyclic or polycyclic C₃₋₂₀ cycloalkyl, C₂₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, each of which except hydrogen and fluorine is substituted or unsubstituted, each R¹ optionally including as part of its structure one or more groups chosen from —O—, —C(O)—, —C(O)—O—, or —S—, and the R¹ groups together optionally forming a ring; and R² is C₁₋₂₀ alkyl, monocyclic or polycyclic C₃₋₂₀ cycloalkyl, C₂₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably C₁₋₆ alkyl or monocyclic or polycyclic C₃₋₁₀ cycloalkyl, each of which is substituted or unsubstituted, R² optionally including as part of its structure one or more groups chosen from —O—, —C(O)—, —C(O)—O—, or —S—, and one R¹ together with R² optionally forming a ring.

3. The photoresist composition of claim 1, wherein the acid-sensitive polymer further comprises a second repeating unit formed from a monomer comprising a lactone group.

4. The photoresist composition of claim 3, wherein the second repeating unit is formed from a monomer of formula (5): 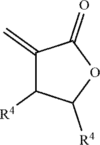
wherein R⁴ is independently hydrogen or C₁₋₃ alkyl.

5. The photoresist composition of claim 1, wherein the acid-sensitive polymer is completely free of aromatic groups.

6. The photoresist composition of claim 1, further comprising a photo-decomposable quencher.

7. The photoresist composition of claim 1, wherein the material comprising a base-labile group is a polymer present in the photoresist composition in an amount from 1 to 10 wt% based on total solids of the photoresist composition.

8. The photoresist composition of claim 1, wherein the photoacid generator compound is an onium salt chosen from aromatic and non-aromatic sulfonates.

9. A pattern formation method, comprising:
(a) applying a layer of a photoresist composition of claim 1 on a substrate;
(b) pattern-wise exposing the photoresist composition layer to activating radiation; and
(c) developing the exposed photoresist composition layer to provide a resist relief image.

10. The pattern formation method of claim 9, wherein the ester acetal group is of the formula (1) 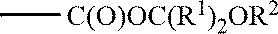
wherein: R¹ is independently hydrogen, fluorine, C₁₋₂₀ alkyl, monocyclic or polycyclic C₃₋₂₀ cycloalkyl, C₂₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, each of which except hydrogen and fluorine is substituted or unsubstituted, each R¹ optionally including as part of its structure one or more groups chosen from —O—, —C(O)—, —C(O)—O—, or —S—, and the R¹ groups together optionally forming a ring; and R² is C₁₋₂₀ alkyl, monocyclic or polycyclic C₃₋₂₀ cycloalkyl, C₂₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably C₁₋₆ alkyl or monocyclic or polycyclic C₃₋₁₀ cycloalkyl, each of which is substituted or unsubstituted, R² optionally including as part of its structure one or more groups chosen from —O—, —C(O)—, —C(O)—O—, or —S—, and one R¹ together with R² optionally forming a ring.

11. The pattern formation method of claim 9, wherein the acid-sensitive polymer further comprises a second repeating unit formed from a monomer comprising a lactone group.

12. The pattern formation method of claim 11, wherein the second repeating unit is formed from a monomer of formula (5): 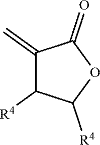
wherein R⁴ is independently hydrogen or C₁₋₃ alkyl.

13. The pattern formation method of claim 9, wherein the acid-sensitive polymer is completely free of aromatic groups.

14. The pattern formation method of claim 9, further comprising a photo-decomposable quencher.

15. The pattern formation method of claim 9, wherein the material comprising a base-labile group is a polymer present in the photoresist composition in an amount from 1 to 10 wt% based on total solids of the photoresist composition.

16. The pattern formation method of claim 9, wherein the photoacid generator compound is an onium salt chosen from aromatic and non-aromatic sulfonates.
